(19) United States
(12) Patent Application Publication
(10) Pub. No.: US 2026/0290679 A1
(43) Pub. Date: Sep. 24, 2026

(54) INTERNALLY-COOLED ACTUATOR COIL

(71) Applicant: ASML Netherlands B.V., Veldhoven (NL)

(72) Inventor: Joost VERSTEIJLEN, Utrecht (NL)

(73) Assignee: ASML Netherlands B.V., Veldhoven (NL)

(21) Appl. No.: 19/469,973

(22) PCT Filed: Mar. 22, 2024
(86) PCT No.: PCT/EP2024/057825

§ 371 Date: Sep. 26, 2025

(30) Foreign Application Priority Data
Apr. 7, 2023 (EP) 23167210.6
Jun. 27, 2023 (EP) 23181744.6

(51) Int. Cl. H01F 27/28; G03F 7/00; H01F 27/32; H01F 41/063; H01F 41/12

(52) U.S. Cl. CPC H01F 27/2876; G03F 7/70758; H01F 27/2823; H01F 27/322; H01F 27/327; H01F 41/063; H01F 41/125

(57) ABSTRACT

A coil to be fluid-cooled for use in electromagnetic actuators of lithography apparatuses, the coil formed of a plurality of electrically-insulated flat wire coil conductors and configured to conduct an electric current to generate an electromagnetic field during use, and at least one cooling fluid channel in heat-conducting contact with the coil, for guiding a flow of cooling fluid to withdraw heat from the coil, the cooling fluid channel being provided across the coil, crossing through multiple of the coil conductors.

### CROSS-REFERENCE TO RELATED APPLICATIONS

This application claims priority of EP applications 23167210.6 which was filed on 7 Apr. 2023 and EP application 23181744.6 which was filed on 27 Jun. 2023, and which are incorporated herein in their entirety by reference.

### FIELD

The present invention relates to a coil to be fluid-cooled for use in electromagnetic actuators of lithography apparatuses. The present invention further relates to an exposure apparatus, for example a lithography apparatus, comprising the coil and to a method of manufacturing the coil.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Magnetic coils currently form the backbone of, for example, electromagnetic actuators. Such actuators are, for example, often used in exposure apparatuses, such as lithography apparatuses for manufacturing semiconductor products. These coils are subjected to an alternating electric current through their conductors, which conductors are often called “windings” due to their typical manufacturing by means of winding. The electric current through the coil induces an electromagnetic field that is capable of interacting with magnets, such as permanent magnets, for effecting a mutual displacement between them.

During use, the magnetic coils need to be cooled, because they tend to heat-up as a result of the electrical resistance of the electric current through the coil. This is typically done by means of a cooling fluid that is passed along the coil through a cooling conduit, to withdraw heat from the coil into the cooling fluid. The cooling fluid is typically a liquid cooling fluid, although gaseous cooling fluids or evaporation cooling fluids are also being utilized.

In current coils, the cooling is rather inefficient, because there are multiple layers of material between the coil and the cooling fluid, which layers typically all have a poor thermal conductivity. Examples of these, starting from the coil, are coil winding insulation, coil winding bonding layers, potting of the coil, electrical insulation foil, insulation foil adhesive and cooling conduit material. In these current coils, it is usually preferable to keep the thermal resistance sufficiently low by making all these layers as thin as possible. The limited thicknesses of the layers, however, introduce higher thermal shear stresses, which can lead to delamination of the layers and which can also increase the risk of electrical breakdown or short-circuiting between the coil and the cooling conduit, since the known cooling conduits are typically made of electrically conducting material. Furthermore, the direction of the thermal path is aligned parallel to the path of the magnetic force between the coil and the magnet, which implies that an accumulation of thermal stresses and stresses resulting from magnetic forces could lead to further delamination and therefore overheating, since this delamination would further reduce thermal conductivity.

As a potential solution, it is known to provide coils with hollow windings, through which the cooling fluid can be circulated. This may enable a more direct contact between the material of the coil windings and the cooling fluid, but it was found disadvantageous, since it may involve a relatively large cooling fluid pressure drop, since the cooling fluid will need to pass over the entire length of the coil windings, and a relatively low coil fill factor, i.e. a large electric resistance and low current density. Furthermore, these hollow coils may have a minimal manufacturable wire size and form factor too large for the current applications. Finally, the coating of the inside of these long thin wires with insulating and non-corroding coating material can be complicated.

As a further alternative, it is known to submerge coils in cooling fluids directly. These coils, however, may have the disadvantage that actuation forces from the coil all have to flow via the core of the coil, which may lead to high stresses in the coil and at the coil-to-core interface. Furthermore, when the whole coil housing is filled with cooling fluid, it may lead to relatively large stresses in the housing, due to the high coolant pressures and acceleration induced pressure fluctuations.

### SUMMARY

In view of the above, it is an object of the present invention to provide a coil that can be cooled in an improved manner, with fewer heat losses, and/or that can operate at larger electric currents without overheating, and/or that can be manufactured at lower cost. It is a further object of the present invention to provide an exposure apparatus with such a coil and to provide a method of manufacturing such a coil.

The present invention thereby provides a coil to be fluid-cooled for use in electromagnetic actuators of lithography apparatuses, the coil being formed of a plurality of electrically-insulated flat wire coil conductors and configured to conduct an electric current to generate an electromagnetic field during use, and comprises at least one cooling fluid channel in heat-conducting contact with the coil, for guiding a flow of cooling fluid to withdraw heat from the coil, characterized in that the cooling fluid channel is provided across the coil, crossing through multiple of the coil conductors.

According to the present invention, the coil is formed by the conductors through which an electric current can be guided. These conductors are sometimes referred to as windings, given that coils can be manufactured by winding a wire in an annular shape to obtain the conductor. Alternatively, however, the present invention also envisages coils that are of the so-called ‘hair-pin’ type, of which the coil is assembled of various separate and interconnected conductors.

The present coil is made of flat wire coil conductors, which is to be understood that adjacent conductors or windings are in contact with each other over a relatively large width, for example compared to their thickness in a stacking direction of the coil. Compared to other coils, for example where the conductors may have a circular cross-section, the flat wire coil conductors may give the benefit that the heat transfer between individual conductors, i.e. in the stacking direction, can be improved already. Furthermore, flat wire coil conductors may enable more conductors in the same cross section, compared to circular windings, which may lower electrical resistance, thereby lowering required voltages over the coil and heat losses in the coil. Moreover, the individual conductors are electrically insulated from each other, to prevent short-circuiting from occurring between them.

The cooling fluid channel in the coil is configured to guide the cooling fluid, so that heat from conductors of the coil can be conducted towards the cooling fluid. The present invention thereby adds that the cooling fluid channel is provided across the coil, which implies that, during use, the cooling fluid is passed through recesses or bores of the coil and that the cooling fluid directly contacts the coil conductors, optionally only through a relatively thin coil coating applied on the conductors in the cooling fluid channel.

The present coils may be manufactured by machining the coil to shape the cooling fluid channels therein. This may, for example, be done by forming open-faced grooves in the coil conductors or by drilling holes through the coil conductors, through which the cooling fluid can be guided.

The cooling fluid channels are provided through multiple of the conductors, so that the cooling fluid is in direct contact with more than a single conductor. This no longer requires heat to dissipate between conductors before dissipating towards the cooling fluid, which may improve the cooling efficiency.

Preferably, the cooling fluid channel extends across substantially all of the coil conductors, to be able to withdraw heat from each conductor into the cooling fluid directly, which may further improve the cooling efficiency of the coil.

The present coil, with the direct contact between the cooling fluid and the conductors, may provide for improved cooling, up to a factor four, because the thermal path between the coil conductors and the cooling fluid is reduced. The thermal path of the present coil is now from coil conductors to coil insulation to cooling fluid. Furthermore, the surface area of the coil in contact with the cooling fluid can be increased in the same coil volume, which also improves the cooling.

Furthermore, the present coil can operate at higher temperatures. In existing coils, thermal stresses between the coil and cooling plate, i.e. resulting from differences in thermal expansion coefficients, did cause delamination of the layers between the coil and the cooling plate. In the present coil, the direction of the thermal shear stress and the thermal path is different from the force path, which may prevent that thermal stresses and magnetic coil forces may no longer contribute to delamination of the coil, enabling larger force densities in the coil.

Furthermore, the present coil no longer requires the separate cooling conduits aside the coil, which may provide more space for the coils in the electromagnetic actuator, which may further contribute to an improved higher force density. Finally, the absence of cooling plates may provide that the coils can be positioned closer to the magnets of the electromagnetic actuator, which may increase the force density as well. The overall combination of the above improvements may lead to more than a factor two increase in magnetic force density.

In addition, the absence of the coils being located close to cooling conduits may provide that the risk of electrical breakdown can be reduced. Furthermore, the absence of cooling fluid running through a housing of the electromagnetic actuator or the cooling conduits may provide that different materials can be used for manufacturing the actuator housing, such as ceramic materials, e.g. because the risk of stress corrosion cracking is avoided in the absence of water, or other materials that are not electrically conductive. This may further contribute in avoiding risks of electrical breakdown.

In an embodiment of the invention, the coil conductors extend in a coil plane. The coil conductors may be arranged next to each other in a stacking direction, which may either be aligned in the coil plane, to obtain a circular, rectangular or a so-called ‘racetrack’ coil. In such a coil, the cooling fluid channel may extend across the coil in a direction having at least a component substantially parallel to the coil plane. Alternatively, however, the stacking direction may be aligned perpendicular to the coil plane, i.e. in an ‘edge-wound’ type of coil, whereby the cooling fluid channel may extend across the coil in a direction having at least a component substantially perpendicular to the coil plane. In both examples, the cooling fluid channels may extend parallel, or may at least have a component extending parallel, to the stacking direction of the coil.

In an embodiment, the cooling fluid channel is formed by at least one bore, crossing transversely through the coil conductors. The bores may be fully defined inside the coil conductors, so that the cooling fluid can contact the conductors at the entire perimeter of the bore. The bores extend transversely through coil, i.e. parallel to the stacking direction, and typically extend through all of the conductors, in order to effectively withdraw heat from all conductors. Optionally, the coil comprise multiple bores extending next to each other, to be able to withdraw heat at multiple different locations in each conductor.

In an alternative embodiment, the cooling fluid channel is formed by at least one groove, extending across the coil conductors at an inner surface, an outer surface or a head end surface of the coil. These grooves are open-faced, for example having a rectangular or rounded cross-section, and are formed into the coil conductors at their respective surface, i.e. so that the cooling fluid may contact the conductors at three sides. The inner surface may be defined as the surface within the central aperture of the coil, the outer surface as surrounding the outermost conductor and the head end surface of the coil may be provided at the head ends of the coil, opposing each other in the stacking direction.

In an embodiment, the groove cooling fluid channel may be provided with a cover element, which is provided to cover the open-faced grooves, in order to provide an enclosed cooling fluid channel and to prevent leakage of cooling fluid.

In an embodiment, a plurality of the coils, for example two coils, may be provided, which may be arranged next to each other, whereby the coil planes of the coils extend parallel to each other, so that the coils together are able to generate a combined magnetic field. The coils may be arranged adjacent to each other with their head end surfaces, which may be electrically insulated from each other through an electrically-insulating layer and wherein the cooling fluid channel is formed by combined grooves in each of the coils. The grooves in the opposed coils oppose each other as well, so that they together delimit a fluid flow path for the cooling fluid and that both coils can be cooled through a single flow of cooling fluid.

Alternatively, the multiple coils may be arranged concentric with each other, i.e. an inner coil in the central aperture of an outer coil. The inner surface of an outer one of the coils and the outer surface of an inner one of the coils thereby contact each other through an electrically-insulating layer. In this embodiment, the grooves of the coils face and oppose each other, for example an inner groove at the inner surface of the outer one of the coils facing an outer groove at the outer surface of the inner one of the coils, so that they together delimit a cooling fluid channel for the cooling fluid and that both coils can be cooled through a single flow of cooling fluid. In both these embodiments, the cooling can be established conveniently and efficiently for multiple coils with a single, but shared cooling fluid channel, which may further improve cooling efficiency and which may further reduce costs.

Seen in cross-section, the grooves may have a depth, perpendicular to the surface in which they are defined, that is relatively shallow compared to the width of the grooves. Grooves with such cross-section may be able to effectively withdraw heat from the coils, but may give rise to relatively large stresses in between the opposed coils, as a result of hydraulic fluid pressures of the cooling fluid in the opposed, i.e. wide grooves. Alternatively, the grooves may be relatively deep, compared to their width, so that the stresses induced at the interface of the between the conductors and the cooling fluid circuit, i.e. resulting from the hydraulic fluid pressure, may become less. Furthermore, the spacing between the adjacent grooves, seen along the surface in which they are defined, may be adjusted to adjust stresses resulting from the hydraulic fluid pressure and the cooling capacity the cooling fluid.

In an embodiment, the coil comprises a coating on the coil conductors in the cooling fluid channel. The coating may be arranged at the surfaces that delimit the cooling fluid channel and may serve various purposes, for example being an anti-corrosive coating, an electrically insulating coating and/or a sealing coating, to prevent leakage of the cooling fluid.

For example, the coating may comprise multiple different coating layers. For example, the coating may comprise one or more ceramic coating layers, made of a ceramic material. As an example, the ceramic coating layers may be made of diamond-like carbon (DLC) or aluminum nitride, which ceramic materials were found to have desirable anti-corrosive, electric insulation and heat-conducting properties. Additionally or alternatively, the coating may comprise one or more polymeric coating layers, for example made of Parylene. The polymeric coating layer may be beneficial in addition to ceramic coating layers, since the ceramic coating may have pinholes in it, which pinholes can be filled with the polymeric material. The one or more polymeric coating layers may be applied on the one or more ceramic coating layers or directly on the coil conductors, for example underneath the ceramic coating layers, i.e. as an intermediate layer to improve adhesion of the ceramic coating layers. Additionally or alternatively, the coating may comprise a multilayer coating comprising one or more polymeric layers, for example made of Parylene and one or more atomic layer deposition (ALD) coatings, for example made of inorganic materials like aluminum oxide, titanium oxide and hafnium oxide.

In an embodiment, the coil further comprises a cooling fluid connector, in fluid connection with the cooling fluid channel, wherein the cooling fluid connector is connectable to an external cooling fluid source, and wherein the cooling fluid connector is arranged in a central aperture of the coil, surrounded by the coil conductors. The cooling fluid connector is configured to receive the cooling fluid flow, from the cooling fluid source, and is configured to guide the cooling fluid flow into the cooling fluid channel. The cooling fluid connector can be advantageously accommodated in the central aperture of the coil, so that the outer surface of the coil is substantially exposed, so that magnets of the electromagnetic actuator can be positioned in close proximity to the coil or that the volume of the coil may be increased in the same housing size. Alternatively, however, the cooling fluid connector may be positioned outside the coil as well.

In an embodiment, the cooling fluid channel describes an annular path across the coil, extending in a circumferential direction along the coil conductors. The cooling fluid channel thereby substantially follows the path of the conductors. This may be beneficial where the coil is embodied as a racetrack coil with all conductors lying in a single coil plane.

In an alternative embodiment, the cooling fluid channel describes a meandering, back-and-forth path across the coil. The meandering path may imply that the cooling fluid channel may transversely extend across the various coil conductors, in order to contact a large number of conductors at a relatively large number of locations along their path, in order to improve the cooling efficiency. In an embodiment, the cooling fluid channel is subdivided in at least one supply section and at least one return section, which are fluidly connected in series, wherein the at least one supply section and the at least one return section extend adjacent to each other through the coil, and wherein the at least one supply section and the at least one return section are anti-parallel with each other, so that a flow direction of the cooling fluid in the at least one supply section is opposite to a flow direction of the cooling fluid in the at least one return section. The supply section and the return section extend next to each other, so that a counter-flow type of heat exchanger may be obtained at each point along the path of the cooling fluid. The cooling fluid in the supply section, just coming out of the cooling fluid source, may be relatively cold, whereas the cooling fluid in the return section, having passed the coil for a larger length, may be relatively warm. The net cooling fluid temperature, i.e. of the combined cooling fluid flows in the supply and return section, may be relatively constant over the length of the cooling fluid channel, which may offer a more even withdrawal of heat from the conductors. The supply section and the return section may be fluidly interconnected in series by means of a reversal turn at their ends.

In a further embodiment, the coil comprises two of the supply sections and a single one of the return sections, wherein the return section is arranged centrally in between both supply sections. Seen at any point along the length of the cooling fluid channel, the return section is surrounded by a supply section on opposite sides. The outermost sections of the cooling fluid channel, during use, contains cooling fluid at the lowest temperature. This may be beneficial at the outermost or innermost edge conductors of the coil. These conductors may not be intersectable with a cooling fluid channel, i.e. where embodied as grooves, since that might give rise to leakage. To this effect, the edge conductors are located close to the coldest cooling fluid in the supply section, located outward of the return section, to maximize the cooling in the edge conductors.

In an alternative embodiment, the cooling fluid channel may primarily extend along the coil conductors, while making back-and-forth side steps across smaller number of various coil conductors, for example two or three, in order to create turbulence in the cooling fluid flow, which may spread the current density and the heat generation over the coil conductors, and improve the cooling effect. The cooling fluid channel is subdivided in at least one supply section and at least one return section, which are fluidly connected in series. Preferably, the supply sections are arranged as the innermost and outermost sections of the cooling fluid channels, such that the innermost and outermost sections of the cooling fluid channels, during use, contains cooling fluid at the lowest temperature. This may be beneficial at the outermost or innermost edge conductors of the coil. These conductors may not be intersectable with a cooling fluid channel, i.e. where embodied as grooves, since that might give rise to leakage. To this effect, the edge conductors are located close to the coldest cooling fluid in the supply section, located outward of the return section, to maximize the cooling in the edge conductors. A cooling liquid manifold may optionally be arranged in the core of the coil, for delivering and receiving the cooling fluid in a spatially efficient way.

In an alternative embodiment, the at least one supply section and the at least one return section describe a double spiral path through the coil. The supply section and the return section thereby still extend alongside each other, but substantially follow the path of the conductors in a spiral manner.

In an embodiment, the flat wire coil conductors have rectangular cross-sections, for example being elongate in a direction perpendicular to the stacking direction. As such, the relatively long sides of the conductors lie against each other, whereas the short sides of the conductors from the head end of the coil. This may be beneficial for the cooling of the coil, because the large adjacent interfaces between the conductors may allow for a relatively large degree of mutual heat exchange between the conductors and because the distance between each winding and the cooling fluid circuit can be minimized, whilst still having conductors with a sufficiently large cross-section.

In yet another embodiment, the coil being elongate in a direction perpendicular to the stacking direction has a rectangular shape with rounded corners seen along the stacking direction. The cooling fluid channel may be arranged to extend across the coil conductors in a direction substantially perpendicular to the coil plane, so parallel to the stacking direction, and typically extend through all of the conductors. The cooling fluid channel may be formed by bores with a round cross-section. The bores may equally spread over the perimeter of the conductors or over the length of each side of the rectangular conductors. The bores may be drilled through the coil conductors. Cooling fluid may be supplied and returned at opposite head end surfaces of the coil.

In an alternative embodiment, the coil being elongate in a direction perpendicular to the stacking direction has a rectangular shape with rounded corners seen along the stacking direction. A V-shaped cooling fluid channel may be arranged to extend across the coil in a plane parallel to the stacking direction, and typically extend through all of the conductors. The V-shaped cooling fluid comprises a supply section and a return section, such that the cooling fluid is supplied to and returned from the same head end surface of the coil. The V-shaped cooling fluid channel may be provided in each side of the coil. More than one V-shaped cooling fluid channels may be arranged in one or more sides of the coil. The cooling fluid channel may be chosen in other forms than a V-shape for achieving a similar cooling effect. The cooling fluid channel may be formed by bores with a round cross-section. The bores may be formed by drilling through various coil conductors, and a fluid connection point may be formed by the drilling process, such that the supply section and the return section are fluidly connected.

In an exemplary embodiment, the rectangular cross-section of the flat wire coil conductors may be a substantially square cross-section.

The present invention further provides an exposure apparatus, for example a lithography apparatus, comprising a coil as disclosed herein. The exposure apparatus, i.e. the coil thereof, may comprise one or more of the features and/or benefits disclosed herein in relation to the coil according to the present invention, for example as recited in the claims. The coil may be used in an electromagnetic actuator of the exposure apparatus, or may, alternatively or additionally, be employed in linear actuators, rotational actuators, inductors, transformers, inverters or the like.

The present invention finally provides a method of manufacturing the coil as disclosed herein, the method comprising the steps of:
forming the coil from a plurality of flat wire coil conductors, and
forming the cooling fluid channel across the coil. The method, i.e. the coil manufactured therewith, may involve one or more of the features and/or benefits disclosed herein in relation to the coil according to the present invention, for example as recited in the claims.

The present method may be beneficial as a result of the cooling fluid channels being formed in the coil, instead of relying on separate cooling conduits that need to be bonded to the coil, as is the case in current manufacturing methods. The forming of the cooling fluid channels is preferably, although not necessarily, carried out after the forming of the coil. This forming of the coil may involve winding of the flat wire coil conductors, i.e. to obtain the coil with windings, but may alternatively comprise forming a hair-pin type of coil, by assembling a number of separate and interconnected conductor sections to form the coil.

In an embodiment, the method further comprises the step of bonding the coil conductors to hold the coil conductors together. The optional bonding may improve the structural rigidity of the coil, but is not essential for forming the cooling fluid channel across the coil.

In an embodiment, the step of forming of the cooling fluid channel comprises subtractive manufacturing of the cooling fluid channel, for example laser ablating, etching, drilling, milling or spark eroding. During subtractive manufacturing, material is removed from the coil, by which the cooling fluid channels are obtained.

In an embodiment, the step of forming of the cooling fluid channel comprises drilling at least one bore transversely through multiple, for example all coil conductors. The drilled cooling fluid bores may be fully surrounded by the coil conductors, so that the cooling fluid can contact the conductors at the entire perimeter of the bore. The bores extend transversely through the coil, i.e. parallel to the stacking direction, and typically extend through all of the conductors, in order to effectively withdraw heat from all conductors. Optionally, the method comprises the step of drilling multiple bores through the coil, extending next to each other, to provide a coil that is able to withdraw heat at multiple different locations in each conductor.

In an alternative embodiment, the step of forming of the cooling fluid channel comprises milling at least one groove through the coil conductors. The milled grooves in the coil are open-faced, for example having a rectangular cross-section, and are formed in the coil conductors at their respective surface, so that the cooling fluid contacts the conductors at the largest possible surface.

In an embodiment, the method further comprises the step of applying a coating on the coil conductors in the cooling fluid channel, for example applying the coating by means of physical vapor deposition and/or (plasma enhanced) chemical vapor deposition. The coating may comprise one or more ceramic coating layers, made of a ceramic material. As an example, the ceramic coating layers may be made of diamond-like carbon (DLC) or aluminum nitride, which ceramic materials can be coated on a surface by means of vapor deposition methods in a suitable manner. Additionally or alternatively, the coating may comprise one or more polymeric coating layers, for example made of Parylene, which may be applied on the coil conductors or on the one or more ceramic coating layers. Additionally or alternatively, the coating may comprise a multilayer coating comprising one or more polymeric layers, for example made of Parylene and one or more atomic layer deposition (ALD) coatings, for example made of inorganic materials like aluminum oxide, titanium oxide and hafnium oxide.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a detailed view of a part of the lithographic apparatus of FIG. 1;

FIG. 3 schematically depicts a position control system;

FIG. 4 depicts a plan view on an embodiment of the coil according to the present invention,

FIG. 5 depicts a plan view on a different embodiment of the coil,

FIG. 6 depicts a plan view on a different embodiment of the coil,

FIG. 7 depicts a side view on an embodiment of the coil,

FIG. 8 depicts a side view on a different embodiment of the coil,

FIG. 9 depicts a plan view on a further embodiment of the coil,

FIG. 10 depicts a perspective cross-sectional view on another embodiment of the coil,

FIG. 11 depicts a cross-sectional view on the coil in FIG. 9 along line A-A,

FIG. 12 depicts a perspective cross-sectional view on an alternative embodiment of the coil,

FIG. 13 depicts a cross-sectional view on a further alternative embodiment of the coil,

FIG. 14 depicts a cross-sectional view on a further embodiment of the coil,

FIG. 15 depicts a perspective view on a further alternative embodiment of the coil,

FIG. 16 depicts a perspective view on a further alternative embodiment of the coil,

FIG. 17 depicts a perspective view on a further embodiment of the coil,

FIG. 18 depicts a plan view on a further embodiment of the coil,

FIG. 19(a) depicts a perspective view on a further embodiment of the coil,

FIG. 19(b) depicts a cross-sectional perspective view on the coil in FIG. 19(a) along line 19B-19B,

FIG. 20(a) depicts a perspective view on a further alternative embodiment of the coil, and

FIG. 20(b) depicts a cross-sectional perspective view on the coil in FIG. 20(a) along line 20B-20B.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

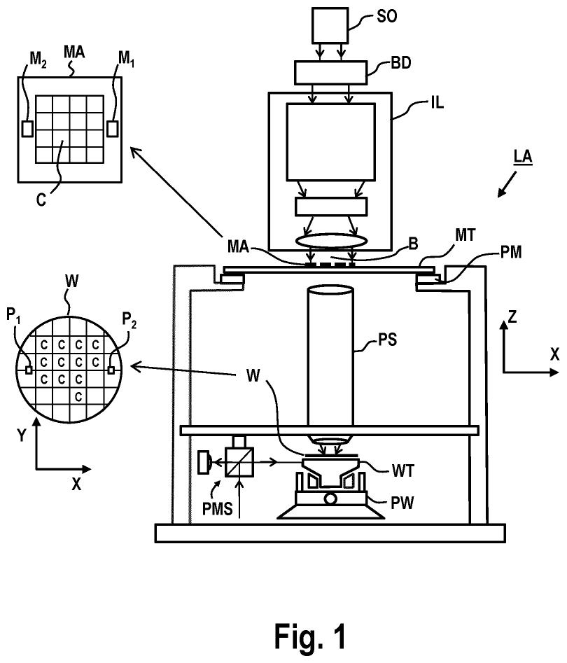

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

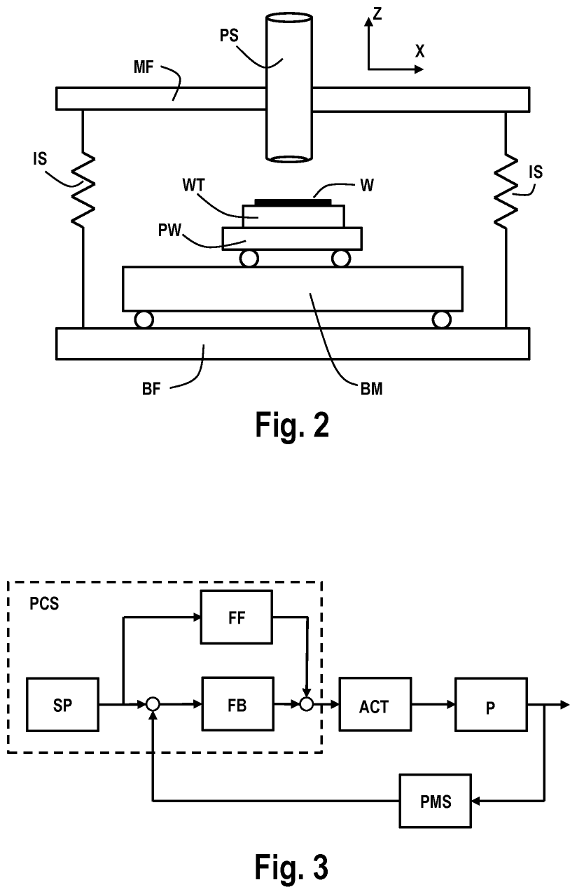

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor. a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads are arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electromagnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

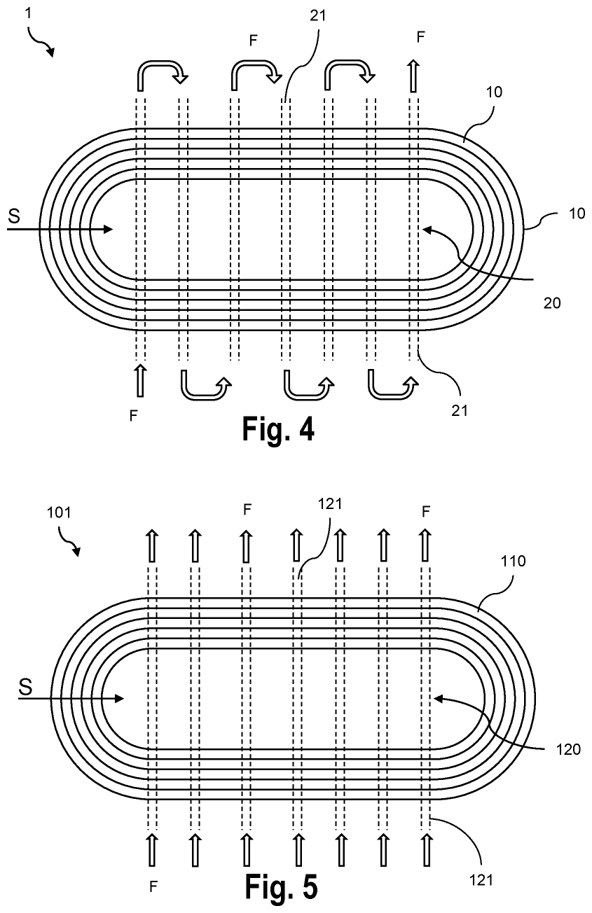

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

In FIG. 4, a first embodiment of the coil according to the present invention is displayed, to which is referred with reference numeral 1. The coil 1 comprises a plurality of coil conductors 10, i.e. windings, which are formed of a plurality of electrically-insulated flat wires. In the schematic representation of FIG. 4, the coil 1 comprises five conductors 10, although it is to be understood that, in practice, the coil may comprise a much larger number of conductors.

All coils shown in the figures comprise coil conductors that are manufactured by winding a wire in an annular shape to obtain the conductor. In view of this, coil conductors are sometimes also referred to as ‘windings’ of the coil. Alternatively, however, the present invention also envisages coils that are of the so-called ‘hair-pin’ type, of which the coil is assembled of various separate and interconnected conductors.

The coil conductors 10 are configured to conduct an electric current to generate an electromagnetic field during use. The plane of FIG. 4 is aligned parallel to a coil plane of the coil conductors 10, wherein the electromagnetic field is to be emitted from this coil 1 in a direction perpendicular to the coil plane and the plane of FIG. 4. The coil conductors 10 are arranged next to each other in a stacking direction S, which is aligned in the coil plane, to obtain a so-called ‘racetrack’ coil. In fact, the coil conductors 10 are shown in the figures as concentric annuli for the sake of clear representation, whereas the coil conductors in fact may together describe a spiral path.

The present coil 1 is made of flat wire coil conductors 10, wherein the term “flat wire” is to be understood that adjacent conductors 10 are in contact with each other over a relatively large width, i.e. compared to their thickness in the stacking direction S. In the representation of FIG. 4, the conductors 10 have a large height in a direction perpendicular to the coil plane and the plane of the drawing, compared to their thickness in the stacking direction S. Compared to other coils, for example where the conductors may have a circular cross-section, the flat wire coil conductors may give the benefit that the heat transfer between individual conductors 10 in the stacking direction S is improved already.

The coil 1 further comprises a cooling fluid channel 20, which extends across the coil 1 in a direction substantially parallel to the coil plane. The cooling fluid channel 20 is formed by a plurality of bores 21 which extend transversely through all of the coil conductors 10. The cooling fluid channel 20 is in heat conductive contact with the coil conductors 10. During use, a flow F of cooling fluid is guided through the cooling fluid channel 20, so that heat from the coil conductors can be transferred to the cooling fluid.

In the coil 1 shown in FIG. 4, the cooling fluid extends through the cooling fluid channel 20 in a back-and-forth path. Hence, the flow direction of the cooling fluid is reversed between the adjacent bores 21, as is indicated by the arrows in FIG. 4, so that the cooling fluid flows in opposite directions in the adjacent bores 21. This implies that all bores 21 in the coil 1 are fluidly connected in series.

FIG. 5 shows an alternative embodiment of the coil 101, in which the cooling fluid channel 120 is formed by adjacent through bores 121 as well, similar as in FIG. 4. In the embodiment of FIG. 5, however, the direction of the cooling fluid flow F in each of the bores 121 are aligned parallel to each other, which implies that all bores 121 in the coil 101 extend through the coil conductors 110 in parallel.

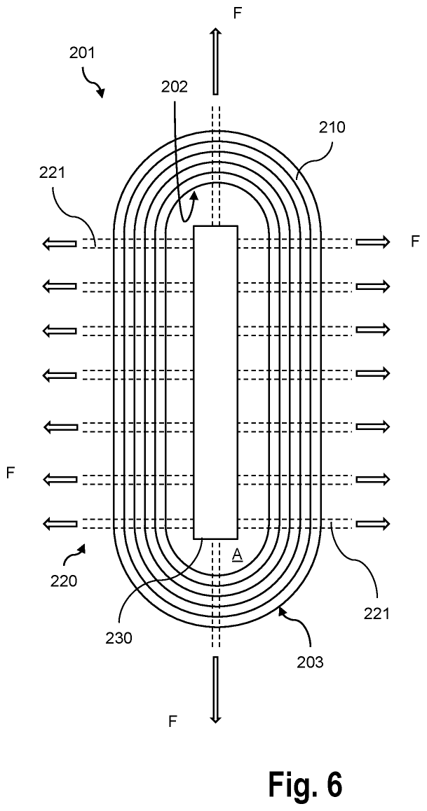

FIG. 6 depicts a further alternative embodiment of the coil 201, in which the cooling fluid channel 220 comprises a plurality of transverse bores 221, which are spread over the perimeter of the conductors 210. The bores 221 thereby extend from an inner surface 202 of the coil 201 towards an outer surface 203 thereof, with a cooling fluid flow F being directed from inside the coil 201 towards the outside. Likewise, further alternative embodiments of the coil may envisage a cooling fluid channel composed of transverse bores in which the cooling fluid flow is directed from outside the coil towards the inside, i.e. opposite to the flow in FIG. 6.

The coil 201 further comprises a cooling fluid connector 230, which is in fluid connection with the bores 221 of the cooling fluid channel 220. The cooling fluid connector 230 is connectable to an external cooling fluid source, not visible in the drawings, from which a flow F of cooling fluid can be received during use. The cooling fluid connector 230 is arranged in a central aperture A of the coil 201, so that it is surrounded by the coil conductors 210. The cooling fluid connector 230 is configured to receive the cooling fluid flow from the cooling fluid source and is configured to guide the cooling fluid flow F into the cooling fluid channel 220. The position of the cooling fluid connector 230 in the central aperture A of the coil 201 is advantageous, because the outer surface 203 of the coil 201 is substantially exposed, so that magnets of the electromagnetic actuator can be positioned in close proximity to the coil 201.

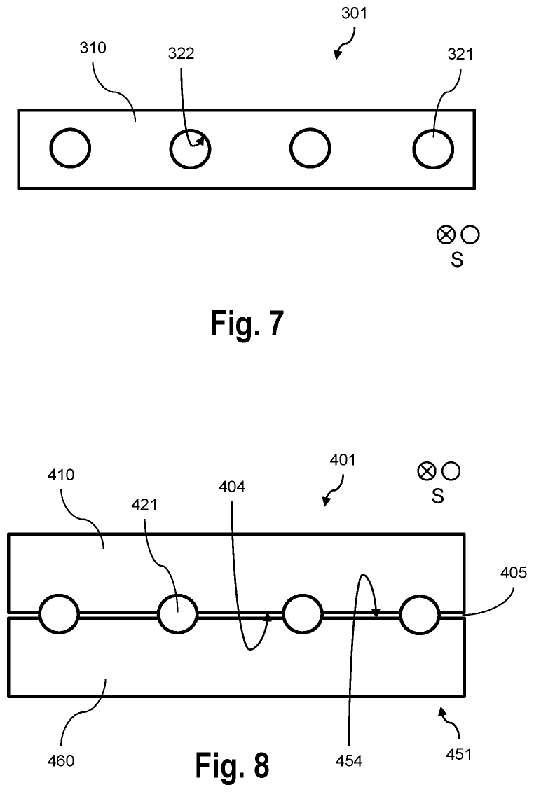

FIG. 7 depicts a side view on an embodiment of the coil 301. The coil 301 in FIG. 7 is a racetrack coil as well, wherein the viewing direction is aligned parallel to the stacking direction S of the coil 301. FIG. 7 shows that the coil 301 comprises a cooling fluid channel that is composed of four through bores 321, which extend transversely through all of the stacked coil conductors 310 in a direction parallel to the stacking direction S. It is visible in FIG. 7 that the drilled cooling fluid bores 321 are fully surrounded by the coil conductors 310, so that the cooling fluid can contact the conductors 310 at the entire perimeter of the bore 321.

In the present embodiment, the bores 321 all comprise a coating 322 that is applied on the coil conductors 310. However, the presence of a coating may not be necessarily essential for all of the bores. The coating 322 is arranged at the perimeter surface that delimits the bores 321 inside the coil conductors 310. The present coating 322 is an anti-corrosive, electrically insulating coating and heat-conducting and comprises multiple different coating layers. The coating 322 first comprises a ceramic coating layer, applied directly on the coil conductors 310 and made of diamond-like carbon (DLC), a ceramic material having desirable anti-corrosive, electric insulation and heat-conducting properties. Additionally, the coating 322 comprises a polymeric coating layer, made of Parylene, applied on the ceramic coating layer. The polymeric coating layer is beneficial in addition to ceramic coating layer, since the ceramic coating may have pinholes in it, which pinholes are filled with the polymeric material. The coating 322 is applied in the bores 321 by means of a chemical vapor deposition process.

FIG. 8 depicts a side view of a different embodiment, which comprises a first coil 401 and a second coil 451, which are arranged next to each other. The coil planes of the coils 401, 451 extend parallel to each other, i.e. perpendicular to the plane of the drawing, so that the coils 401, 451 together are able to generate a combined magnetic field. The coils 401, 451 face each other with their head end surfaces 404, 454, which are electrically insulated from each other through an electrically-insulating layer 405. The cooling fluid channel is formed by bores 421 that are provided at the interface of the coils 401, 451. As such, the cooling fluid will contact both the coil conductors 410 of the first coil 401 and the coil conductors 460 of the second coil 451 during use, so that heat can be withdrawn into the cooling fluid from both of the coils 401, 451.

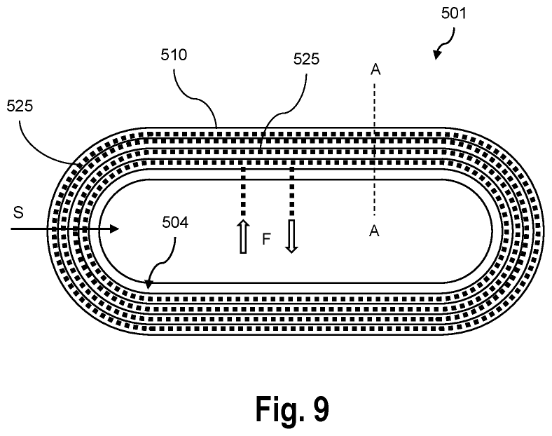

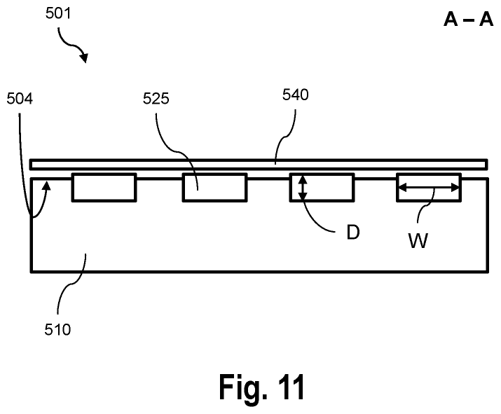

FIG. 9 depicts a plan view on a further embodiment of the coil 501, in which the cooling fluid channel is formed by four open-faced grooves 525, which are indicated by means of the dashed lines in FIG. 9. In FIG. 11, the same coil 501 is shown in a cross-sectional view. The grooves 525 are, in this embodiment, provided in the head end surface 504 of the coil 501, which is the plane of the drawing of FIG. 8. The cooling fluid channel describe an annular path across the head end surface 504 of the coil 501, extending in a circumferential direction along the coil conductors 510. The grooves 525 of the cooling fluid channel thereby substantially follow the path of the conductors 510, which is beneficial in the present embodiment where the coil is embodied as a racetrack coil 501 with all conductors 510 lying in a single coil plane, i.e. parallel to the plane of the drawing.

The grooves 525 of the cooling fluid channel are formed in the conductors 510 of the coil 501 by means of a subtractive manufacturing method, whereby material is removed from the coil conductors 510. In the present embodiment, the cooling fluid channel is obtained by milling the grooves 525 through the coil conductors 510 at the head end surface 504 of the coil 501.

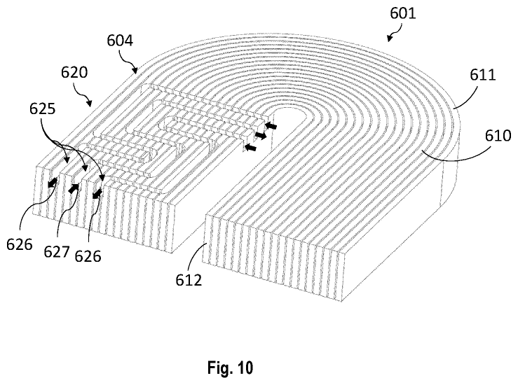

FIG. 10 depicts a perspective cross-sectional on another embodiment of the coil 601, in which the cooling fluid channel 620 describes a meandering, back-and-forth path across the head end surface 604 of the coil 601. This cooling fluid channel 620 is also formed by grooves 625, of which the meandering path implies that they transversely extend across the various coil conductors 610.

The cooling fluid channel 620 is furthermore subdivided in two grooves forming supply sections 626 and a single groove forming a return section 627 for the cooling fluid. The supply and return sections are fluidly connected in series and extend adjacent to each other through the coil 601. The supply sections 626 and the return section 627 are aligned anti-parallel with each other, so that a flow direction of the cooling fluid in the supply sections is opposite to a flow direction of the cooling fluid in the return section, as is indicated by means of the arrows in FIG. 10. The cooling fluid in the supply sections 626, just coming out of the cooling fluid source, may be relatively cold, whereas the cooling fluid in the return section 627, having passed the coil 601 for a larger length, may be relatively warm. The net cooling fluid temperature, i.e. of the combined cooling fluid flows in the supply and return section, may be relatively constant over the length of the cooling fluid channel 620, which may offer a more even withdrawal of heat from the conductors 610.

The return section 627 is arranged centrally in between both supply sections 626, so that, seen at any point along the length of the cooling fluid channel 620, the return section 627 is surrounded by a supply section 626 on opposite sides. The outward placement of the supply sections 626 implies that the outermost sections of the cooling fluid channel 620, during use, contain cooling fluid at the lowest temperature. This may be beneficial at the outermost edge conductor 611 and innermost edge conductor 612 of the coil 601, which only lie against other conductors 610 at one side, to maximize the cooling in the edge conductors 611, 612. FIG. 11 depicts a cross-sectional view on the coil 501 in FIG. 9 along line A-A, which shows that the four grooves 525 are provided in the conductors 510 at the head end surface 504 of the coil 501. For the sake of clarity, the conductors 510 are depicted as a single conductor in FIG. 11.

The grooves 525 may have a rectangular cross-section, so that the cooling fluid may contact the conductors 510 at three sides of the grooves 525, although other types of cross-sections can also be envisaged, such as semi-circular or rounded cross-sections. The grooves 525 have a depth D, perpendicular to the head end surface 504 that is relatively shallow compared to their width W in the stacking direction S. Alternatively, however, the grooves may be provided relatively deep, compared to their width. In another alternative embodiment the grooves may have a round or rounded cross-section.

The coil 501 is further provided with a cover element 540 over the grooves 525, in order to cover the open-faced grooves 525 from above and to provide an enclosed cooling fluid channel, to prevent leakage of cooling fluid.

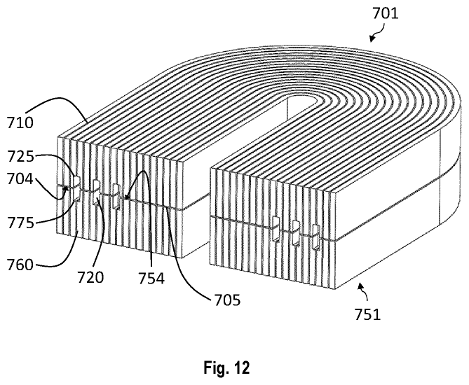

FIG. 12 depicts a cross-sectional view on an alternative embodiment, in which a first coil 701 is arranged adjacent to a second coil 751, in a manner similar to the embodiment in FIG. 8. The coil planes of the coils 701, 751 extend parallel to each other, so that the coils 701, 751 together are able to generate a combined magnetic field. The coils 701, 751 face each other with their head end surfaces 704, 754, which are electrically insulated from each other through an electrically-insulating layer 705. The cooling fluid channel 720 is formed by three grooves 725 in the first coil 701 and three grooves 775 in the second coil 751, which oppose each other, so that they together delimit a fluid flow path for the cooling fluid. In this way, the cooling fluid channel 720 is formed between both coils 701, 751 and both coils 701, 751 can be cooled through a single flow of cooling fluid.

The embodiment in FIG. 12 is manufactured by forming the first coil 701 with the first coil conductors 710 and forming the second coil 751 with the second coil conductors 760 first. Next, the grooves 725, 775 are milled in the head end surfaces 704, 754 of the respective coils 701, 751 and, finally, the coils 701, 751 are arranged adjacent to each other, so that the cooling fluid channel 720 is eventually formed by the respective opposed grooves 725, 775. Optionally after milling the grooves 725, 775 and before arranging the coils 701, 751 adjacent to each other, a coating may be applied to the coils, covering the walls of the grooves 725, 775 and the head end surfaces 704, 754, or over the whole coils. The coating may comprise multiple different coating layers. For example, the coating may comprise one or more ceramic coating layers, made of a ceramic material. As an example, the ceramic coating layers may be made of diamond-like carbon (DLC) or aluminum nitride, which ceramic materials were found to have desirable anti-corrosive, electric insulation and heat-conducting properties. Additionally or alternatively, the coating may comprise one or more polymeric coating layers, for example made of Parylene. The polymeric coating layer may be beneficial in addition to ceramic coating layers, since the ceramic coating may have pinholes in it, which pinholes can be filled with the polymeric material. The one or more polymeric coating layers may be applied on the one or more ceramic coating layers or directly on the coil conductors, for example underneath the ceramic coating layers, i.e. as an intermediate layer to improve adhesion of the ceramic coating layers. Additionally or alternatively, the coating may comprise a multilayer coating comprising one or more polymeric layers, for example made of Parylene and one or more atomic layer deposition (ALD) coatings, for example made of inorganic materials like aluminum oxide, titanium oxide and hafnium oxide. After applying the coating, a glue may then be applied to the head end surfaces 704, 754 to bond the coated coils 701, 751 adjacent to each other, so that the coated cooling fluid channel 720 is formed by the respective opposed grooves 725, 775. The bonding the coated coils may alternatively or additionally be achieved by thermal bonding, by for example first melting at least part of the coating material at above a certain temperature, and then bonding the coated head end surfaces together using the at least partially melted coating material.

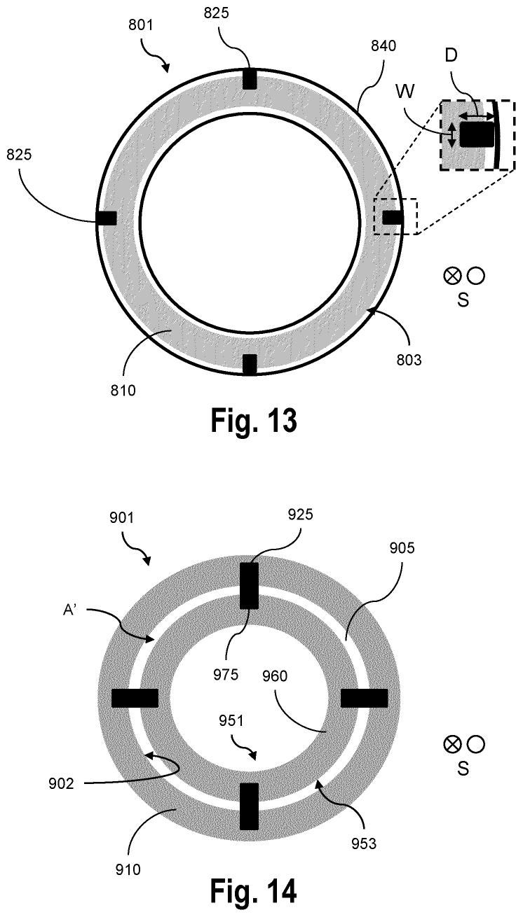

FIG. 13 depicts a cross-sectional view on a further alternative embodiment of the coil 801, which is a so-called ‘edge-wound’ type of coil. In the coil 801 of FIG. 13, the coil plane extends parallel to the plane of the drawing and the stacking direction S is aligned perpendicular to the coil plane and the plane of the drawing. In this coil 801, the cooling fluid channel extends across the coil 801 in a direction substantially perpendicular to the coil plane, so parallel to the stacking direction S. The cooling fluid channel is formed by four grooves 825, which are provided in the outer surface 803 of the coil 801, equally spread over the perimeter of the conductors 810. The coil 801 further comprises a cover element, embodied as a cover ring 840, which surrounds the conductors 810 and which covers the open-faced grooves 825 from the outside, to provide an enclosed cooling fluid channel, to prevent leakage of cooling fluid.

The grooves 825 in the embodiment of FIG. 13 also have a rectangular cross-section, but the relation between their depth D and width W is different relative to the coil as shown in FIG. 11. In the coil 801 of FIG. 13, as best seen in the enlargement in the top-right corner, the grooves 825 have a depth D, seen from the outer surface 803 of the coil 801, that is relatively large compared to their width W along the perimeter of the conductors 810, which implies that these grooves 825 are provided relatively deep, in relation to their width.

FIG. 14 depicts a cross-sectional view on a further embodiment, which comprises a first coil 901 and a second coil 951, which are arranged concentric with each other. The second, e.g. inner, coil 951 is thereby placed in the central aperture A′ of the first, e.g. outer, coil 901 and the coil planes of both coils 901, 951 thereby extend parallel to each other, so that the coils 901, 951 together are able to generate a combined magnetic field. Moreover, the inner surface 902 of the first coil 901 and the outer surface 953 of the second coil 951 thereby contact each other through an electrically-insulating layer 905.

The grooves 925, 975 of the coils 901, 951 face and oppose each other. As such, the cooling fluid channel is formed by four grooves 925 in the inner surface 902 of the conductors 910 of the first coil 901 and four grooves 975 in the outer surface 953 of the conductors 960 of the second coil 951. In this way, both coils 901, 951 can be cooled through a single flow of cooling fluid through the opposed grooves 925, 975. This embodiment of the coil may further be provided free of cover elements on the outer surface of the conductors 910 of the first coil 901 and on the inner surface of the conductors 960 of the second coil 951, because the cooling fluid channel 920 is fully enclosed in between the conductors 910, 960 of both coils 901, 951.

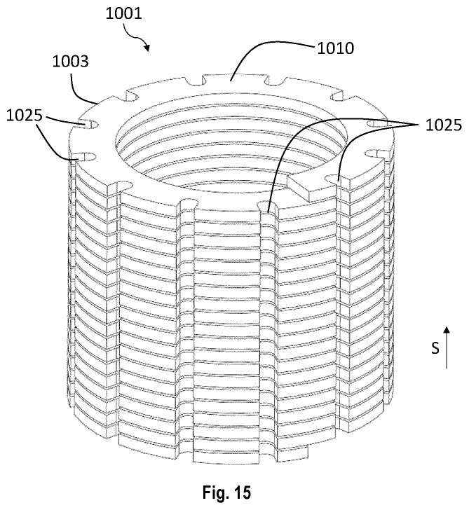

FIG. 15 depicts a perspective view on a further alternative embodiment of the coil 1001, which is a so-called ‘edge-wound’ type of coil. In the coil 1001 of FIG. 15, the coil plane extends perpendicular to the stacking direction S. In this coil 1001, the cooling fluid channel extends across the coil 1001 in a direction substantially perpendicular to the coil plane, so parallel to the stacking direction S. The cooling fluid channel is formed by grooves 1025, which are provided in the outer surface 1003 of the coil 1001, equally spread over the perimeter of the conductors 1010. The grooves 1025 are open-faced and having a rounded cross-section.

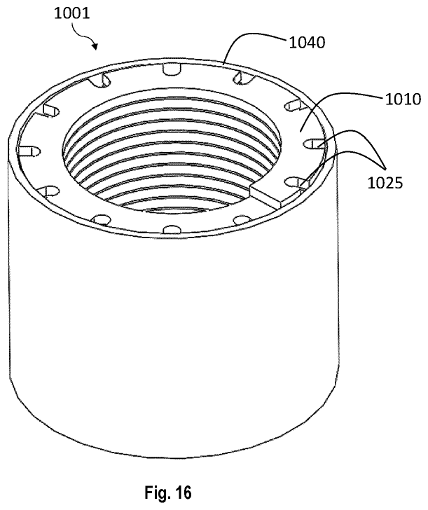

The coil 1001 depicted in FIG. 15 may further comprise a cover element as depicted in FIG. 16, embodied as a cover ring 1040, which surrounds the conductors 1010 and which covers the open-faced grooves 1025 from the outside, to provide an enclosed cooling fluid channel, to prevent leakage of cooling fluid.

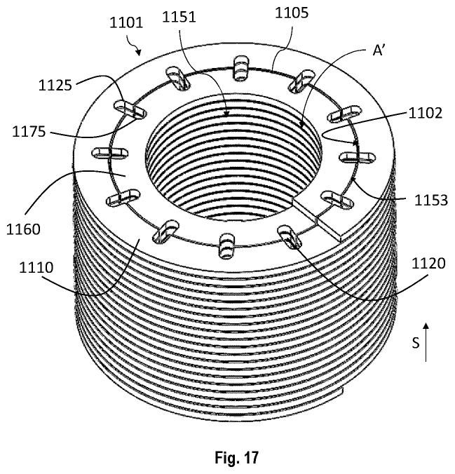

FIG. 17 depicts a perspective view on a further embodiment, which comprises a first coil 1101 and a second coil 1151, which are arranged concentric with each other. The second, e.g. inner, coil 1151 is thereby placed in the central aperture A′ of the first, e.g. outer, coil 1101 and the coil planes of both coils 1101, 1151 thereby extend parallel to each other, so that the coils 1101, 1151 together are able to generate a combined magnetic field. Moreover, the inner surface 1102 of the first coil 1101 and the outer surface 1153 of the second coil 1151 thereby contact each other through an electrically-insulating layer 1105.

The grooves 1125, 1175 of the coils 1101, 1151 face and oppose each other, having a rounded cross-section. As such, the cooling fluid channel is formed by grooves 1125 in the inner surface 1102 of the conductors 1110 of the first coil 1101 and grooves 1175 in the outer surface 1153 of the conductors 1160 of the second coil 1151. In this way, both coils 1101, 1151 can be cooled through a single flow of cooling fluid through the opposed grooves 1125, 1175. This embodiment of the coil may further be provided free of cover elements on the outer surface of the conductors 1110 of the first coil 1101 and on the inner surface of the conductors 1160 of the second coil 1151, because the cooling fluid channel 1120 is fully enclosed in between the conductors 1110, 1160 of both coils 1101, 1151.

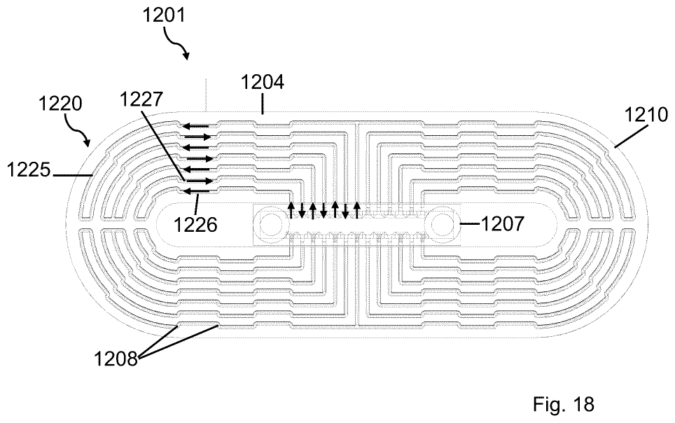

FIG. 18 depicts a plan view on another embodiment of the coil 1201, in which the cooling fluid channel 1220 describes a meandering, back-and-forth path across the head end surface 1204 of coil 1201, which is the plane of the drawing of the figure. Similar to grooves 625 in FIG. 10, this cooling fluid channel 1220 is also formed by open-faced grooves 1225. Compared to the coil of FIG. 10, the meandering path in FIG. 18 implies that they extend primarily along the coil conductors, while making back-and-forth side steps 1208 across smaller number of the various coil conductors 1210, for example two or three. The side steps create turbulence in the cooling fluid flow, which may spread the current density and the heat generation over the coil conductors, and improve the cooling effect. There is provided at least one supply section 1226 and at least on return section 1227 of the cooling fluid channel 1220, which are fluidly connected in series. Preferably, the supply sections are arranged as the innermost and outermost sections of the cooling fluid channel, such that the innermost and outermost sections of the cooling fluid channel, during use, contains cooling fluid at the lowest temperature. This may be beneficial at the outermost or innermost edge conductors of the coil. These conductors may not be intersectable with a cooling fluid channel, i.e. where embodied as grooves, since that might give rise to leakage. To this effect, the edge conductors are located close to the coldest cooling fluid in the supply section, located outward of the return section, to maximize the cooling in the edge conductors.

The supply sections and the return sections are aligned substantially antiparallel with each other, so that a flow direction of the cooling fluid in the supply sections is opposite to a flow direction of the cooling fluid in the return section, as is indicated by means of the arrows in FIG. 18. The cooling fluid in the supply sections 1226, coming out of the cooling fluid source, may be relatively cold, whereas the cooling fluid in the return sections 1227, having passed the coil 1201 for a larger length, may be relatively warm. The net cooling fluid temperature, i.e. of the combined cooling fluid flows in the supply and return sections, may be relatively constant over the length of the cooling fluid channel 1220, which may offer a more even withdrawal of heat from the conductors 1210. Optionally, a cooling fluid manifold 1207 may be arranged in the core 1206 of the coil, for delivering and receiving the cooling fluid to and from the supply sections 1226 and return sections 1227, in a spatially efficient way.

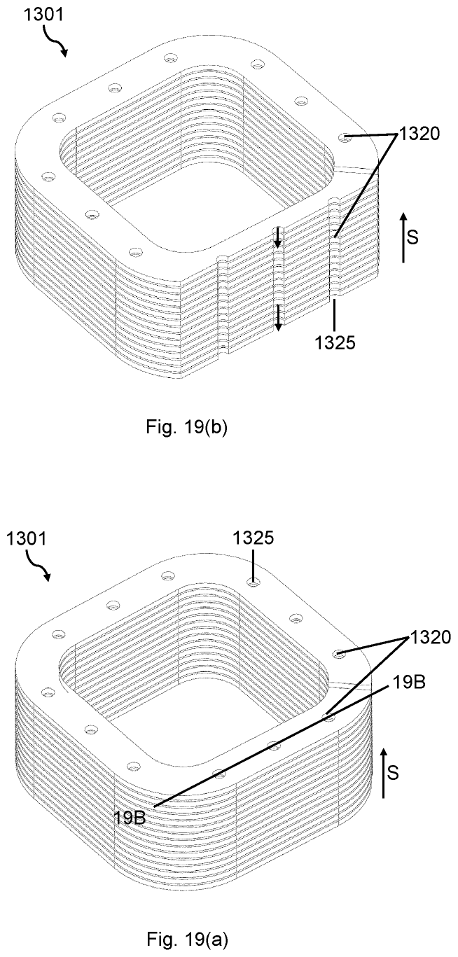

FIG. 19(a) depicts a perspective view on a further embodiment of the coil 1301, which comprises an “edge wound” type of coil having rectangular shape with rounded corners seen along the stacking direction S. In the coil 1301, the coil plane extends perpendicular to the stacking direction S. FIG. 19(b) is a cross-sectional perspective view of the coil 1301 cut along the line 19B-19B and perpendicular to the coil plane. In this coil 1301, the cooling fluid channel 1320 extends across the coil 1301 in a direction substantially perpendicular to the coil plane, so parallel to the stacking direction S. The cooling fluid channel is formed by bores 1325 with a round cross-section, which are provided in the coil 1301, equally spread over the length of each side of the conductors 1310. Preferably the bores 1325 are drilled through the coil conductors. In this coil 1301, cooling fluid may be supplied and returned at opposite head end surfaces of the coil, for example, supplied from the top and returned from the bottom of the coil, as shown by the arrows in FIG. 19(b).

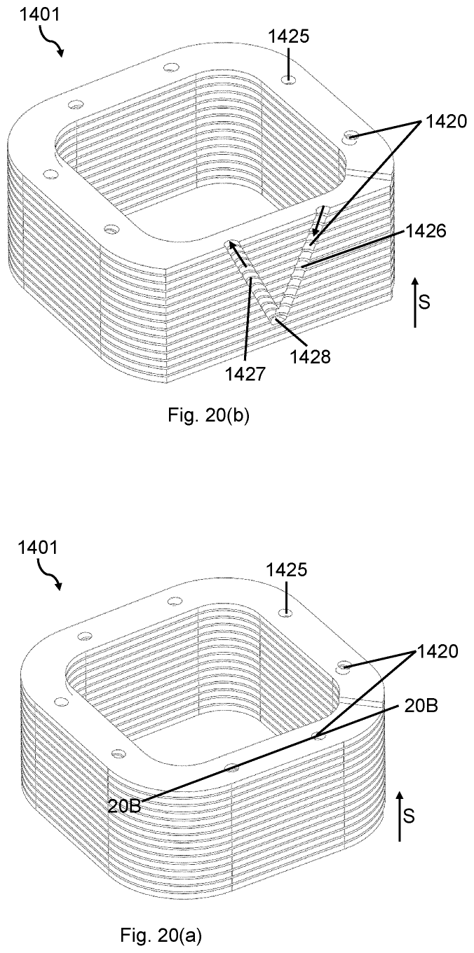

FIG. 20(a) depicts a perspective view on an alternative embodiment of the coil 1401, which comprises an “edge wound” type of coil having rectangular shape with rounded corners seen along the stacking direction S. In the coil 1401, the coil plane extends perpendicular to the stacking direction S. FIG. 20(b) is a cross-sectional perspective view of the coil 1401 cut along the line 20B-20B and perpendicular to the coil plane. In this coil 1401, a V-shaped cooling fluid channel 1420 extends across the coil 1401 in a plane parallel to the stacking direction S. Typically, the cooling fluid channel extends through all of the conductors. The V-shaped cooling fluid channel comprises a supply section 1426 and a return section 1427, such that the cooling fluid is supplied to and returned from the same head end surface of the coil as shown by the arrows in FIG. 20(b). The V-shaped cooling fluid channel are provided in each side of the coil 1401. Optionally, more than one V-shaped cooling fluid channel may be arranged in each side of the coil. Alternatively, other shapes of the cooling fluid channel may be chosen for achieving a similar cooling effect. The cooling fluid channel is formed by bores 1425 with a round cross-section. Preferably the supply section bores and the return section bores are drilled through various coil conductors, and a connecting point 1408 is formed by the drilling process, such that the supply section 1426 and the return section 1427 are fluidly connected.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. A coil to be fluid-cooled for use in electromagnetic actuators of lithography apparatuses, the coil being formed of a plurality of electrically-insulated flat wire coil conductors and configured to conduct an electric current to generate an electromagnetic field during use, and comprising:
at least one cooling fluid channel in heat-conducting contact with the coil, for guiding a flow of cooling fluid to withdraw heat from the coil,
characterized in that,
the cooling fluid channel is provided across the coil, crossing through multiple of the coil conductors.
2. The coil according to clause 1, wherein the cooling fluid channel crosses through substantially all coil conductors.
3. The coil according to clause 1 or 2, wherein the cooling fluid channel extends across the coil in a direction having at least a component substantially parallel to a coil plane in which the coil conductors extend.
4. The coil according to clause 1 or 2, wherein the cooling fluid channel extends across the coil in a direction having at least a component substantially perpendicular to a coil plane in which the coil conductors extend.
5. The coil according to any of the preceding clauses, wherein the cooling fluid channel is formed by at least one bore, crossing transversely through the coil conductors.
6. The coil according to any of the clauses 1-4, wherein the cooling fluid channel is formed by at least one groove, extending across the coil conductors at an inner surface, an outer surface or a head end surface of the coil.
7. The coil according to clause 6, comprising a plurality of the coils,
   wherein the coils are arranged adjacent to each other, with their coil conductors extending parallel to each other and spaced at a distance from each other,
   wherein opposed head ends of the coils contact each other through an electrically-insulating layer, and
   wherein the cooling fluid channel is formed by opposed grooves in each of the coils, each extending across their respective coil conductors at their opposed head end surfaces.
8. The coil according to clause 6, comprising a plurality of the coils,
   wherein the coils are arranged concentric with each other, with their coil conductors extending co-planar with other,
   wherein an inner surface of an outer one of the coils and an outer surface of an inner one of the coils contact each other through an electrically-insulating layer, and
   wherein the cooling fluid channel is formed by opposed grooves in each of the coils, each extending across their respective coil conductors at their opposed inner and outer surfaces.
9. The coil according to any of the clauses 6-8, further comprising a cover element, arranged at the inner surface, outer surface or head end surface of the coil, to cover the groove.
10. The coil according to any of the preceding clauses, further comprising a coating on the coil conductors in the cooling fluid channel.
11. The coil according to clause 10, wherein the coating comprises one or more ceramic coating layers, for example made of diamond-like carbon (DLC) or aluminum nitride, and/or one or more polymeric coating layers, for example made of Parylene.
12. The coil according to any of the preceding clauses, further comprising a cooling fluid connector, in fluid connection with the cooling fluid channel,
   wherein the cooling fluid connector is connectable to an external cooling fluid source, and
   wherein the cooling fluid connector is arranged in a central aperture of the coil, surrounded by the coil conductors.
13. The coil according to any of the preceding clauses, wherein the cooling fluid channel describes an annular path across the coil, extending in a circumferential direction along the coil conductors.
14. The coil according to any of the clauses 1-12, wherein the cooling fluid channel describes a meandering, back-and-forth path across the coil.
15. The coil according to any of the preceding clauses, wherein the cooling fluid channel is subdivided in at least one supply section and at least one return section, which are fluidly connected in series,
   wherein the at least one supply section and the at least one return section extend adjacent to each other through the coil, and
   wherein the at least one supply section and the at least one return section are anti-parallel with each other, so that a flow direction of the cooling fluid in the at least one supply section is opposite to a flow direction of the cooling fluid in the at least one return section.
16. The coil according to clause 15, comprising two of the supply sections and a single one of the return sections, and
   wherein the return section is arranged centrally in between both supply sections.
17. The coil according to clause 15, wherein the at least one supply section and the at least one return section describe a double spiral path through the coil.
18. The coil according to any of the preceding clauses, wherein the flat wire coil conductors have rectangular cross-sections.
19. Exposure apparatus, for example a lithography apparatus, comprising a coil according to any of the preceding clauses.
20. A method of manufacturing the coil according to any of the clauses 1-18, comprising the steps of:
   forming the coil from a plurality of flat wire coil conductors, and
   forming the cooling fluid channel across the coil.
21. The method according to clause 20, wherein the step of forming of the cooling fluid channel comprises subtractive manufacturing of the cooling fluid channel, for example laser ablating, etching, drilling, milling or spark eroding.
22. The method according to clause 20 or 21, wherein the step of forming of the cooling fluid channel comprises drilling at least one bore transversely through multiple, for example all coil conductors.
23. The method according to clause 20 or 21, wherein the step of forming of the cooling fluid channel comprises milling at least one groove through the coil conductors.
24. The method according to any of the clauses 20-23, further comprising the step of applying a coating on the coil conductors in the cooling fluid channel, for example applying the coating by means of physical vapor deposition and/or (plasma enhanced) chemical vapor deposition.

1-15. (canceled)

16. A coil to be fluid-cooled for use in electromagnetic actuators of lithography apparatuses, the coil being formed of a plurality of electrically-insulated flat wire coil conductors extending in a coil plane and configured to conduct an electric current to generate an electromagnetic field during use, the coil comprising:
at least one cooling fluid channel in heat-conducting contact with the coil configured to guide a flow of cooling fluid to withdraw heat from the coil,
wherein the cooling fluid channel is provided across the coil crossing through substantially all the coil conductors.

17. The coil of claim 16, wherein the cooling fluid channel extends across the coil in a direction having at least a component substantially parallel to a stacking direction of the coil.

18. The coil of claim 16, wherein the cooling fluid channel extends across the coil in a direction having at least a component substantially parallel to the coil plane in which the coil conductors extend.

19. The coil of claim 16, wherein the cooling fluid channel extends across the coil in a direction having at least a component substantially perpendicular to the coil plane in which the coil conductors extend.

20. The coil of claim 16, wherein the cooling fluid channel is formed by at least one bore, crossing transversely through the coil conductors.

21. The coil of claim 16, wherein the cooling fluid channel is formed by at least one groove, extending across the coil conductors at an inner surface, an outer surface or a head end surface of the coil.

22. The coil of claim 16, further comprising a coating on the coil conductors in the cooling fluid channel.

23. The coil of claim 22, wherein the coating comprises one or more ceramic coating layers comprising diamond-like carbon (DLC) or aluminum nitride and/or one or more polymeric coating layers comprising Parylene.

24. The coil of claim 16, further comprising:
a cooling fluid connector in fluid connection with the cooling fluid channel,
wherein the cooling fluid connector is connectable to an external cooling fluid source, and
wherein the cooling fluid connector is arranged in a central aperture of the coil, surrounded by the coil conductors.

25. The coil of claim 16, wherein the cooling fluid channel comprises an annular path across the coil, extending in a circumferential direction along the coil conductors.

26. The coil of claim 16, wherein the cooling fluid channel comprises a meandering, back-and-forth path across the coil.

27. The coil of claim 16, wherein:
the cooling fluid channel is subdivided in at least one supply section and at least one return section, which are fluidly connected in series,
the at least one supply section and the at least one return section extending adjacent to each other through the coil; and
the at least one supply section and the at least one return section are anti-parallel with each other, so that a flow direction of the cooling fluid in the at least one supply section is opposite to a flow direction of the cooling fluid in the at least one return section.

28. The coil of claim 16, wherein the flat wire coil conductors have rectangular cross-sections.

29. A lithography apparatus comprising:
the coil according to claim 16.

30. A method of manufacturing comprising:
forming a coil from a plurality of flat wire coil conductors, the coil being fluid-cooled for use in electromagnetic actuators of lithography apparatuses, the coil being formed of a plurality of electrically-insulated flat wire coil conductors extending in a coil plane and configured to conduct an electric current to generate an electromagnetic field during use, the coil comprising at least one cooling fluid channel in heat-conducting contact with the coil configured to guide a flow of cooling fluid to withdraw heat from the coil, the cooling fluid channel being provided across the coil crossing through substantially all the coil conductors; and
forming the cooling fluid channel across the coil.
